(19) United States
(12) Patent Application Publication
(10) Pub. No.: US 2012/0227781 A1
(43) Pub. Date: Sep. 13, 2012

(54) SOLAR CELL SHEET

(76) Inventors: Yoshihito ISHIBASHI, Tokyo (JP); Shigeru Tajima, Kanagawa (JP); Tsukasa Yoshimura, Tokyo (JP)

(21) Appl. No.: 13/045,613

(22) Filed: Mar. 11, 2011

(51) Int. Cl. H01L 31/05

(52) U.S. Cl. 136/244

(57) ABSTRACT

There is provided a solar cell sheet including a solar cell panel that generates electric power by receiving irradiation of sunlight, a first sheet to which a number of the solar cell panels are attached such that a reverse surface of a light receiving surface of each of the solar cell panels is attached to the first sheet with a predetermined interval between each of the solar cell panels, the number of the solar cell panels being sufficient to obtain desired electric power, and a second sheet to which is removably attached to the at least one first sheet to which the solar cell panels are attached, the at least one first sheet being removably attached to the second sheet on a reverse surface to a surface on which the solar cell panels are attached.

### BACKGROUND OF THE INVENTION

1. Field of the Invention

The present invention relates to a solar cell sheet.

2. Description of the Related Art

It is conceivable that usage of solar cell panels, which generate electric power by receiving irradiation of sunlight, will become widespread as a measure against global warming, to reduce the amount of carbon dioxide emissions. A prerequisite of known solar cell panels is that a plurality of solar cells are used in combination on top of a roof, where it is easy to receive the irradiation of sunlight, and the panels are designed and manufactured for permanent installation. As a result, a weight of the panels is great, and it is not easy to move solar cell panels that have once been installed.

With known solar cell panels, although there is some sense that the solar cell panels are used individually in order to receive a supply of electric power, there is a stronger sense that the solar cell panels are used to supplement a supply of electric power, in addition to electric power supplied by an existing power supply network. Thus, the use of known solar cell panels is based on an assumption that they will be used in a region in which a power supply network is already in place.

Known solar cell panels are mainly used in this way in regions in which a power supply network is already provided, but in future, it is expected that demand will increase for solar cell panels to generate electric power in regions that are not provided with a power supply network. In this type of region, for example, a mode can be conceived in which a solar cell panel temporarily stores generated electric power in a battery, and the electric power stored in the battery is then used.

### SUMMARY OF THE INVENTION

In regions in which a power supply network has not been set up, it is conceivable that a photovoltaic power generating system consisting of a solar cell panel and a battery is used while being moved. As described above, as permanent installation is a prerequisite of known solar cell panels, they are not designed to be used while being moved.

Although technology for a portable photovoltaic power generating device is disclosed (in Japanese Patent Application Publication No. 2006-278460, for example), a large number of solar cells is required to obtain a necessary amount of electric power, and it is further preferable for the large number of solar cells to be structured such that they can be efficiently stored. In recent years, there has been progress in the development of thin film flexible solar panels and it is expected that in the future there will be further advances in photovoltaic power generating systems that use such solar cell panels and that offer excellent portability. In this case, it is necessary not only to improve storability of the solar cell panels, but also to improve ease of installation.

In light of the foregoing, it is desirable to provide a new and improved solar cell sheet that offers excellent portability, and that further allows solar cell panels to be easily installed and stored.

According to an embodiment of the present invention, there is provided a solar cell sheet including a solar cell panel that generates electric power by receiving irradiation of sunlight, a first sheet to which a number of the solar cell panels are attached such that a reverse surface of a light receiving surface of each of the solar cell panels is attached to the first sheet with a predetermined interval between each of the solar cell panels, the number of the solar cell panels being sufficient to obtain desired electric power, and a second sheet to which is removably attached to the at least one first sheet to which the solar cell panels are attached, the at least one first sheet being removably attached to the second sheet on a reverse surface to a surface on which the solar cell panels are attached.

The solar cell panels may be attached to the first sheet with a same orientation.

The first sheet may include connector holes through which are passed lead wires, which supply electric power generated by the solar cell panels, and connectors, which connect each of the solar cell panels and the lead wires, the lead wires and the connectors being passed through to the reverse surface to the surface on which the solar cell panels are attached.

The lead wires may be fixed to the reverse surface of the first sheet using surface fasteners.

A shape of the solar cell panel may be a rectangle, and the solar cell panel may be attached such that a lengthwise orientation of the solar cell panel is aligned with a lengthwise orientation of the first sheet.

Two of the solar cell panels may be attached to each one of the first sheets, the solar cell panels being attached with a gap between the solar cell panels such that, when the first sheet is folded over at a gap section between the solar cell panels, the solar cell panels oppose each other and the lead wires which supply the electric power generated by the solar cell panels and the connectors that connect the lead wires to the solar cell panels do not overlap with each other.

A shape of the solar cell panel may be a rectangle and the solar cell panel may be attached such that a lengthwise orientation of the solar cell panel orthogonally intersects with a lengthwise orientation of the first sheet.

An even number of the solar cell panels may be attached to each one of the first sheets, the solar cell panels being attached such that, when the first sheet is folded in the lengthwise direction such that folded over lengths are equal to the even number, a position of the solar cell panels matches.

The solar cell panels may be attached such that the solar cell panels are at a predetermined angle to a long side of the first sheet.

The solar cell panels may be arranged as a mesh when the solar cell panels are attached to the second sheet.

A shape of the solar cell panel may be a square.

The first sheet and the second sheet may be sheets that have flame resistant properties.

According to another embodiment of the present invention, there is provided a solar cell sheet including a solar cell panel that generates electric power by receiving irradiation of sunlight, and a sheet to which a number of the solar cell panels are attached such that a reverse surface of a light receiving surface of each of the solar cell panels is attached to the sheet with a predetermined interval between each of the solar cell panels, the number of the solar cell panels being sufficient to obtain desired electric power.

According to the present invention described above, it is possible to provide a novel and improved solar cell sheet that offers excellent portability and that further allows solar cell panels to be easily installed and stored.

### BRIEF DESCRIPTION OF THE DRAWINGS

FIG. 1 is an explanatory diagram showing a photovoltaic power generating system 1 according to a first embodiment of the present invention;

FIG. 2 is an explanatory diagram showing a structure of a solar cell sheet 100 according to the first embodiment of the present invention;

FIG. 3 is an explanatory diagram showing a structure of a solar cell panel 103 according to the first embodiment of the present invention;

FIG. 4A is an explanatory diagram showing a shape of a connector 104;

FIG. 4B is an explanatory diagram showing the shape of the connector 104;

FIG. 5 is an explanatory diagram showing a structure of a strip-shaped sheet 102 according to the first embodiment of the present invention;

FIG. 6 is an explanatory diagram showing an example of a state in which lead wires 105, first coupling portions 106 and extension cables 107 are fixed to a reverse surface of the strip-shaped sheet 102;

FIG. 7 is an explanatory diagram showing a state in which the lead wire 105 is fixed to the strip-shaped sheet 102 by a surface fastener 112;

FIG. 8 is an explanatory diagram showing a state in which the lead wire 105, the first coupling portion 106 and the extension cable 107 are fixed to the strip-shaped sheet 102 by the surface fastener 112;

FIG. 9 is an explanatory diagram showing an example of a structure of a main sheet 101 according to the first embodiment of the present invention;

FIG. 10 is an explanatory diagram showing an example of the structure of the main sheet 101 according to the first embodiment of the present invention;

FIG. 11 is an explanatory diagram showing the solar cell sheet 100 in a state in which the strip-shaped sheets 102 are attached to the main sheet 101;

FIG. 12 is an explanatory diagram showing a state in which the strip-shaped sheet 102 to which the solar cell panels 103 are attached is folded over in a center section in the lengthwise direction;

FIG. 13 is an explanatory diagram showing a structure of a solar cell sheet 200 according to a second embodiment of the present invention;

FIG. 14 is an explanatory diagram showing a storage example of a strip-shaped sheet 202 according to the second embodiment of the present invention;

FIG. 15 is an explanatory diagram showing connections between solar cell panels 203 and connectors 204 according to the second embodiment of the present invention;

FIG. 16A is an explanatory diagram showing a connection between the solar cell panel 203 and the connector 204;

FIG. 16B is an explanatory diagram showing the connection between the solar cell panel 203 and the connector 204;

FIG. 17 is an explanatory diagram showing an installation example of the solar cell sheet 200 according to the second embodiment of the present invention;

FIG. 18 is an explanatory diagram showing a structure of a solar cell sheet 300 according to a third embodiment of the present invention;

FIG. 19A is an explanatory diagram showing a state in which solar cell panels 303 are attached to a strip-shaped sheet 302 on the solar cell sheet 300 according to the third embodiment of the present invention;

FIG. 19B is an explanatory diagram showing a state in which the solar cell panels 303 are attached to the strip-shaped sheet 302 on the solar cell sheet 300 according to the third embodiment of the present invention; and

FIG. 19C is an explanatory diagram showing a state in which the solar cell panels 303 are attached to the strip-shaped sheet 302 on the solar cell sheet 300 according to the third embodiment of the present invention.

### DETAILED DESCRIPTION OF THE EMBODIMENT(S)

Hereinafter, preferred embodiments of the present invention will be described in detail with reference to the appended drawings. Note that, in this specification and the appended drawings, structural elements that have substantially the same function and structure are denoted with the same reference numerals, and repeated explanation of these structural elements is omitted.

Note that the description will be given in the order shown below.

1. First embodiment

1-1. Structure of photovoltaic power generating system

1-2. Structure of solar cell sheet

1-3. Structure of solar cell panel

1-4. Structure of strip-shaped sheet

1-5. Example of structure of main sheet

2. Second embodiment

3. Third embodiment

4. Conclusion

### 1. FIRST EMBODIMENT

### 1-1. Structure of Photovoltaic Power Generating System

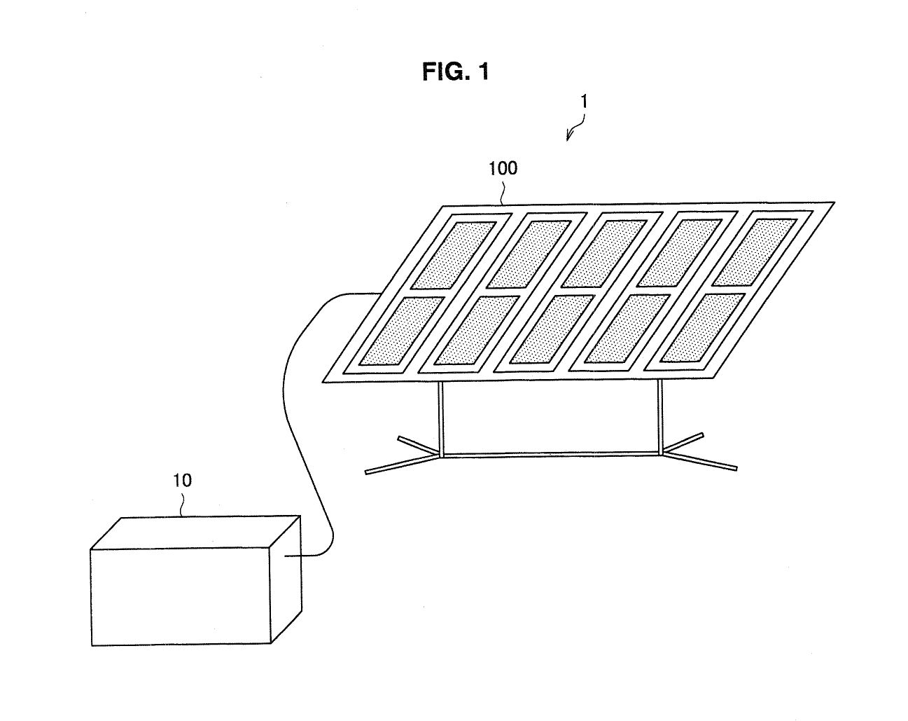

First, a structure of a photovoltaic power generating system 1 according to a first embodiment of the present invention will be explained. FIG. 1 is an explanatory diagram showing a structure of the photovoltaic power generating system 1 according to the first embodiment of the present invention. The photovoltaic power generating system 1 shown in FIG. 1 has a structure in which electric power, which is generated by receiving irradiation of sunlight on a light receiving surface of a solar cell panel, is stored in a battery. Hereinafter, the structure of the photovoltaic power generating system 1 according to the first embodiment of the present invention will be explained with reference to FIG. 1.

As shown in FIG. 1, the photovoltaic power generating system 1 according to the first embodiment of the present invention includes a solar cell sheet 100 that generates electric power by receiving irradiation of sunlight and a battery box 10, in which is provided a battery that stores the electric power generated by the solar cell sheet 100.

In order to increase portability, the solar cell sheet 100 has a structure in which a number of solar cell panels are mounted on a single sheet of sheet material (a main sheet). The number of solar cell panels is the number necessary to obtain a desired electric power. The solar cell panel is attached to a separate sheet, such that the solar cell panel can easily be attached to and removed from the sheet material. The portability of the solar cell sheet 100 is increased by attaching and removing the sheet material, on which the solar cell panel is mounted, to and from the main sheet.

### 1.2 Structure of Solar Cell Sheet

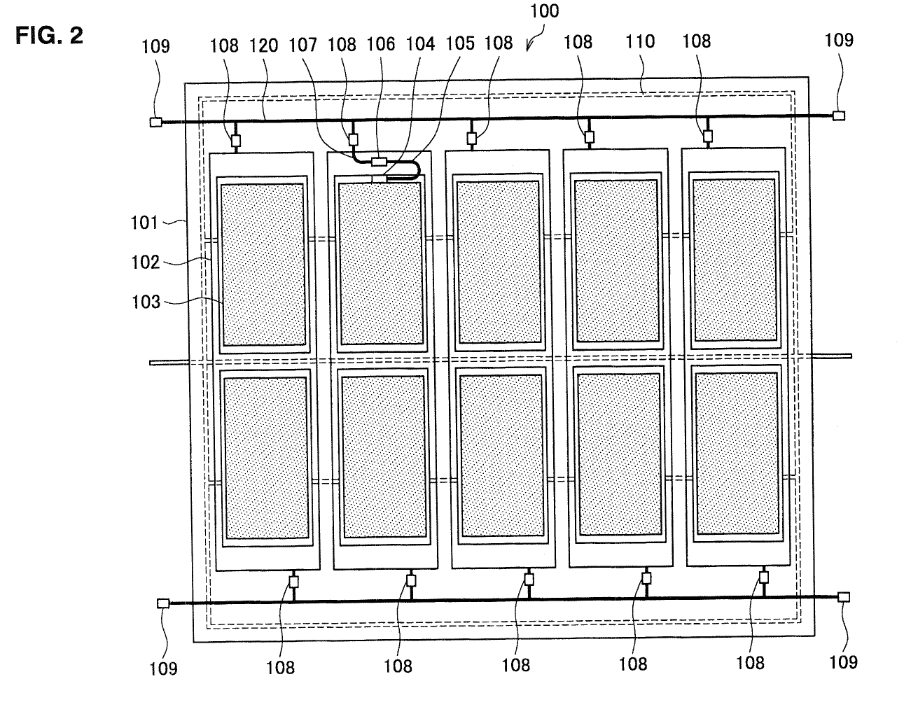

Next, the structure of the solar cell sheet 100 according to the first embodiment of the present invention will be explained. FIG. 2 is an explanatory diagram showing the structure of the solar cell sheet 100 according to the first embodiment of the present invention. In FIG. 2, a state is exemplified in which the solar cell sheet 100 is viewed from above. Hereinafter, the structure of the solar cell sheet 100 according to the first embodiment of the present invention will be explained with reference to FIG. 2.

As shown in FIG. 2, the solar cell sheet 100 according to the first embodiment of the present invention includes a main sheet 101, strip-shaped sheets 102, solar cell panels 103, connectors 104, lead wires 105, first coupling portions 106, extension cables 107, second coupling portions 108, third coupling portions 109, a support 110 and connecting cables 120.

The main sheet 101 is a sheet material onto which are mounted the strip-shaped sheets 102 to which the solar cell panels 103 are attached. The strip-shaped sheet 102 is a sheet material to which the solar cell panels 103 are attached. The strip-shaped sheet 102 is formed to be long and narrow, and is smaller than the main sheet 101, as shown in FIG. 2. A reverse surface of the light-receiving surface of each of the solar cell panels 103 is attached to the strip-shaped sheet 102. Note that the main sheet 101 and the strip-shaped sheet 102 may be formed of sheets that have flame resistant properties. More specifically, the main sheet 101 and the strip-shaped sheet 102 may be formed of heat-resistant polyester tarpaulin.

The solar cell panel 103 is a panel on which is laid a solar cell, and the solar cell generates electric power by receiving irradiation of sunlight. The solar cell panel 103 according to the present embodiment is thin and flexible, and can easily be bent or rolled. In the present embodiment, two of the solar cell panels 103 are arranged in series and attached to a single one of the strip-shaped sheets 102.

Also, in the first embodiment of the present invention, the rectangular solar cell panels 103 are attached to the rectangular strip-shaped sheet 102 such that the lengthwise directions are aligned, as shown in FIG. 2. More specifically, the solar cell panels 103 are attached such that the lengthwise direction of the strip-shaped sheet 102 is aligned with the lengthwise direction of the solar cell panels 103. As shown in FIG. 2, a width of a short edge of the strip-shaped sheet 102 is wider than a width of a short edge of the solar cell panel 103, but the present invention is not limited to this example. The width of the short edge of the strip-shaped sheet 102 may be approximately the same as the width of the short edge of the solar cell panel 103, or may be shorter than the width of the short edge of the solar cell panel 103. Further, the shape of the solar cell panel 103 need not necessarily be rectangular, and the solar cell panel 103 may be a square. In addition, in the example shown in FIG. 2, two of the solar cell panels 103 are attached to the strip-shaped sheet 102, but three or four of the solar cell panels 103 may be attached.

The strip-shaped sheet 102 and the solar cell panel 103 can be attached using a chosen attaching device. However, taking into account a case in which the solar cell panel 103 is broken and needs to be replaced, the solar cell panel 103 need not necessarily be completely adhered to the strip-shaped sheet 102 and the strip-shaped sheet 102 and the solar cell panel 103 may be attached by a surface fastener, for example.

The connector 104 connects the lead wire 105 and the solar cell panel 103. The lead wire 105 is a wire to supply to the battery box 10 the electric power generated by the solar cell panels 103. The first coupling portion 106 is a connector that connects the lead wire 105 to the extension cable 107. Further, the second coupling portion 108 is a connector that connects the extension cable 107 to the connecting cable 120.

Note that connectors with the same structure may be used as the first coupling portions 106 and the second coupling portions 108, or connectors with respectively different structures may be used. In addition, the extension cable 107 shown in FIG. 2 need not necessarily be used and the lead wire 105 may be directly connected to the connecting cable 120.

The support 110 supports the main sheet 101. It goes without saying that, in the present invention, the structure of the support 110 is not limited to the example shown in FIG. 2. However, if the support 110 is structured such that sections of the support 110 are caused to extend from the main sheet 101, as shown in FIG. 2, the main sheet 101 can be installed such that it can be rotated using the extended sections.

As described hereinbelow, since the connector 104, the lead wire 105, the first coupling portion 106 and the extension cable 107 are attached to the strip-shaped sheet 102 such that they are positioned on the reverse surface of the strip-shaped sheet 102, when the solar cell sheet 100 is seen as shown in FIG. 2, these structural members do not appear on the front surface. However, for ease of explanation, in FIG. 2, some of the connectors 104, the lead wires 105, the first coupling portions 106 and the extension cables 107 are shown positioned on the front surface of the strip-shaped sheet 102 such that the positions of these structural members can be understood.

### 1.3 Structure of Solar Cell Panel

Next, a structure of the solar cell panel 103 that is attached to the solar cell sheet 100 according to the first embodiment of the present invention will be explained.

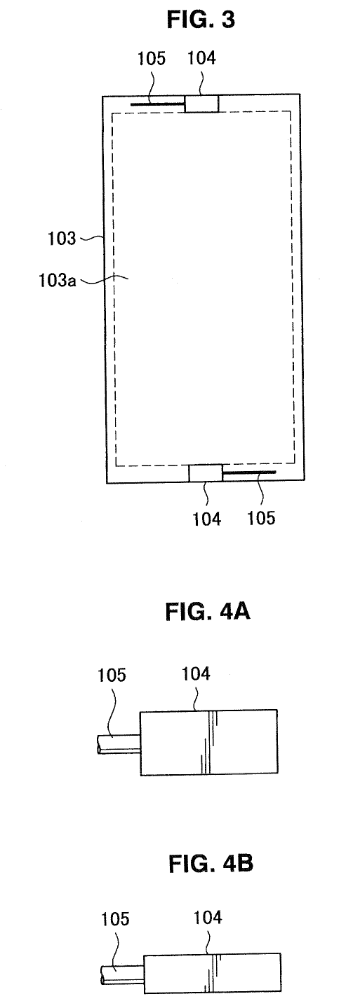

FIG. 3 is an explanatory diagram showing the structure of the solar cell panel 103 according to the first embodiment of the present invention. FIG. 3 shows the solar cell panel 103 as seen from the reverse side of the light receiving surface, namely as seen from the opposite side of a surface on which a solar cell 103a is laid. Hereinafter, the structure of the solar cell panel 103 according to the first embodiment of the present invention will be explained with reference to FIG. 3.

As shown in FIG. 3, the solar cell panel 103 is provided with the connectors 104. The connectors 104 connect the lead wires 105 to the solar cell panel 103 such that electric power, which is generated by the solar cell 103a (that is laid on the solar cell panel 103) receiving irradiation of sunlight, is output to the lead wires 105.

FIG. 4A and FIG. 4B are explanatory diagrams each showing a shape of the connector 104. FIG. 4A shows the connector 104 as seen from above and FIG. 4B shows the connector 104 as seen from a side surface. The connector 104 has a cuboid shape as shown. Then, as shown in FIG. 4A and FIG. 4B, the lead wires 105 respectively extend from the left and right edges of the upper and lower connectors 104 such that the lead wires 105 extend for a predetermined distance. Of course, it goes without saying that the shape of the connector 104 is not limited to the example shown in FIGS. 4A and 4B.

### 1.4 Structure of Strip-Shaped Sheet

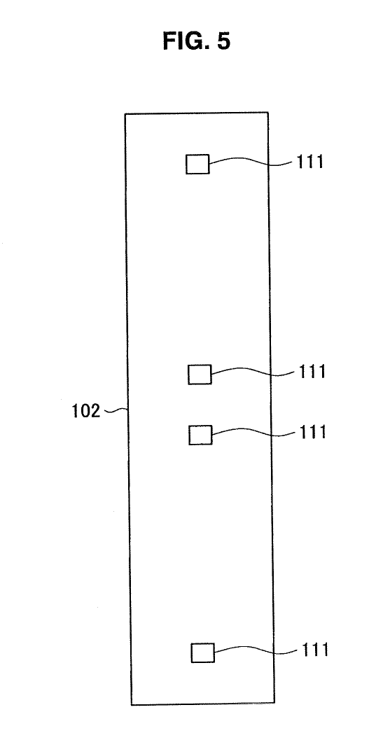

Next, a structure of the strip-shaped sheet 102 to which the solar cell panels 103 are attached will be explained. FIG. 5 is an explanatory diagram showing the structure of the strip-shaped sheet 102 according to the first embodiment of the present invention, and shows a flat surface shape of the strip-shaped sheet 102. Hereinafter, the structure of the strip-shaped sheet 102 according to the first embodiment of the present invention will be explained with reference to FIG. 5.

As shown in FIG. 5, the strip-shaped sheet 102 to which the solar cell panels 103 are attached has a rectangular shape, and, in the present embodiment, a size of the strip-shaped sheet 102 is sufficient such that two of the solar cell panels 103 can be attached to one of the strip-shaped sheets 102. In the following explanation, the surface of the strip-shaped sheet 102 to which the solar cell panels 103 are attached is referred to as a “front surface” and the opposite surface is referred to as a “reverse surface.”

As shown in FIG. 5, the strip-shaped sheet 102 according to the first embodiment of the present invention is provided with four connector holes 111. The connector holes 111 are holes that allow the connectors 104 and the lead wires 105, which are provided on the reverse surface of the solar cell panels 103 (refer to FIG. 3), to be passed through to the reverse surface of the strip-shaped sheet 102 when the solar cell panels 103 are attached to the front surface of the strip-shaped sheet 102. The connector holes 111 are therefore provided in positions that correspond to the positions of the connectors 104 provided on the reverse surface of the solar cell panels 103 when the solar cell panels 103 are attached to the front surface of the strip-shaped sheet 102.

By providing the connector holes 111 in the strip-shaped sheet 102 in this way, the connectors 104 and the lead wires 105 can be positioned on the reverse surface of the strip-shaped sheet 102. By positioning the connectors 104 and the lead wires 105 on the reverse surface of the strip-shaped sheet 102, the lead wires 105 do not emerge onto the front surface of the strip-shaped sheet 102, thus making it possible to avoid any obstruction to the irradiation of sunlight onto the solar cell panel 103.

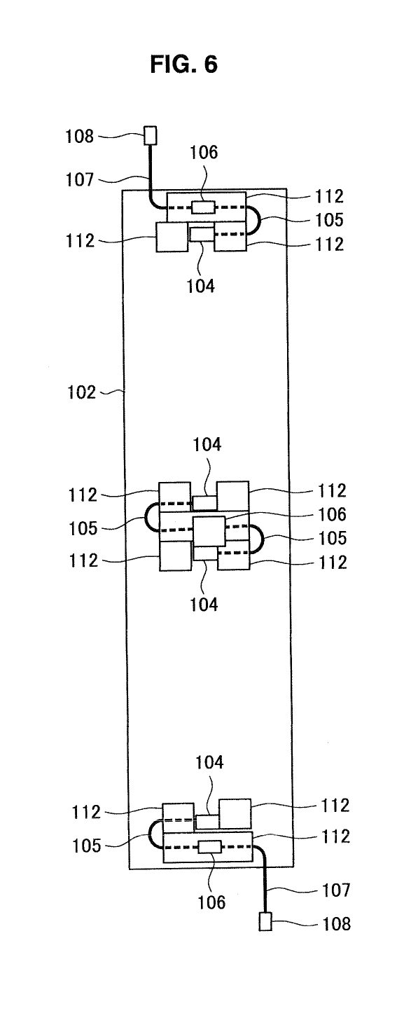

The lead wires 105 may be fixed to the reverse surface of the strip-shaped sheet 102 using surface fasteners. FIG. 6 shows the strip-shaped sheet 102 as seen from the reverse surface and is an explanatory diagram showing an example of a state in which the lead wires 105, the first coupling portions 106 and the extension cables 107 are fixed to the reverse surface of the strip-shaped sheet 102.

In FIG. 6, a state is shown in which the lead wires 105, the first coupling portions 106 and the extension cables 107 are fixed to the reverse surface of the strip-shaped sheet 102 using surface fasteners 112. By fixing the lead wires 105, the first coupling portions 106 and the extension cables 107 to the reverse surface of the strip-shaped sheet 102 using the surface fasteners 112 in this way, it is possible to avoid the cables becoming entangled with each other, and inconvenience is eliminated when mounting the strip-shaped sheet 102, to which the solar cell panels 103 are attached, on the main sheet 101.

Note that the surface fasteners 112 may be prepared in advance on both sides of the connectors 104 to correspond to differences in the shape of the connectors 104, as shown in FIG. 6.

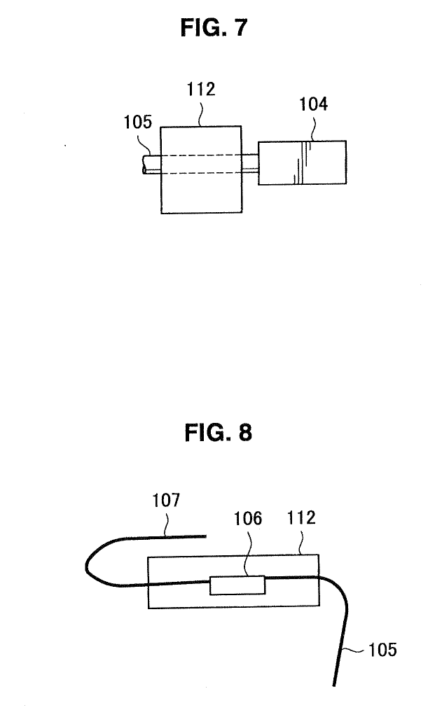

FIG. 7 is an explanatory diagram showing a state in which the lead wire 105 extending from the connector 104 is fixed to the strip-shaped sheet 102 using the surface fastener 112. FIG. 8 is an explanatory diagram showing a state in which the lead wire 105, the first coupling portion 106 and the extension cable 107 are fixed to the strip-shaped sheet 102 using the surface fastener 112.

By using the surface fastener 112 in this way to fix the lead wire 105, the first coupling portion 106 and the extension cable 107 to the reverse surface of the strip-shaped sheet 102, the above-described effects are obtained. Note that, as shown in FIG. 8, a width of the surface fastener used to fix the first coupling portion 106 may be a width sufficient that it can fix the whole of the first coupling portion 106 to the reverse surface of the strip-shaped sheet 102.

### 1.5 Example of Structure of Main Sheet

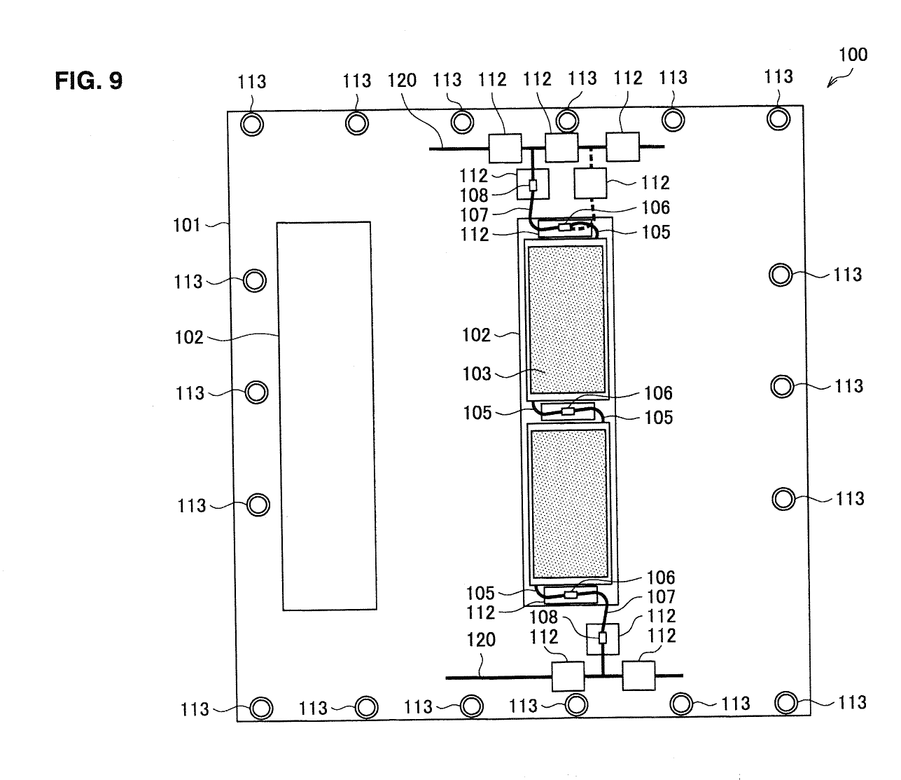

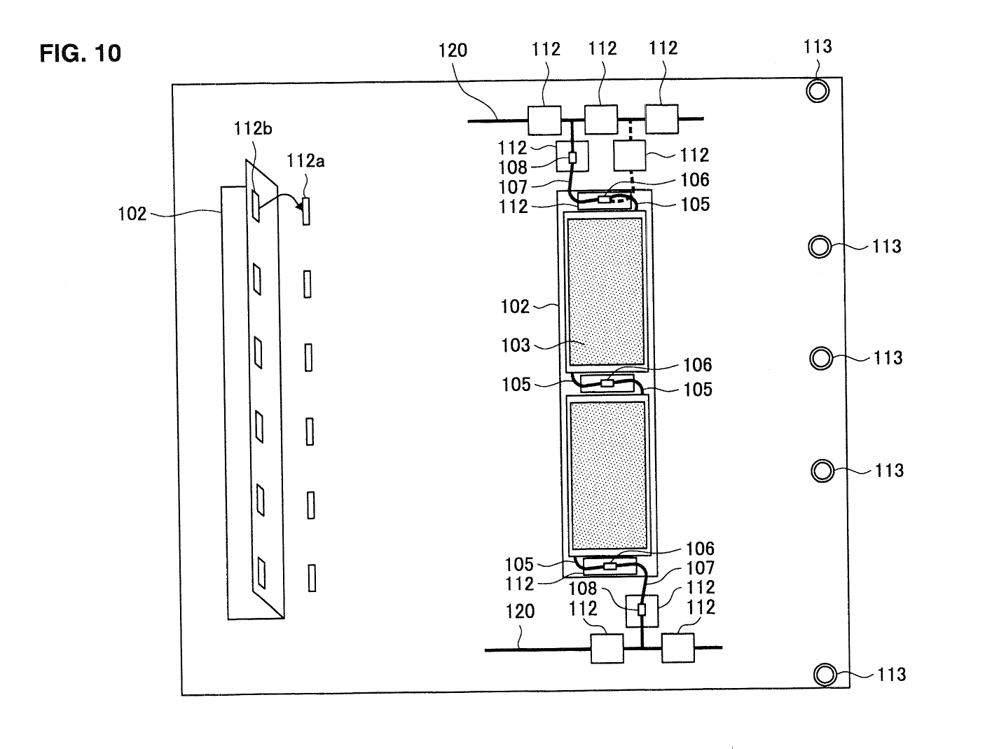

Next, an example of a structure of the main sheet 101 according to the first embodiment of the present invention will be explained. FIG. 9 and FIG. 10 are explanatory diagrams each showing an example of the structure of the main sheet 101 according to the first embodiment of the present invention. Hereinafter, the examples of the structure of the main sheet 101 according to the first embodiment of the present invention will be explained with reference to FIG. 9 and FIG. 10.

FIG. 9 shows a state in which the strip-shaped sheet 102 (to which the solar cell panels 103 are not attached) is attached to the main sheet 101, and a state in which the strip-shaped sheet 102 (to which the solar cell panels 103 are attached) is attached to the main sheet 101.

FIG. 9 and FIG. 10 show a state in which the solar cell panels 103 can be seen, namely a state as seen from the front surface of the main sheet 101. However, for the purpose of explanation, the connectors 104, the lead wires 105, the first coupling portions 106, the extension cables 107 and the surface fasteners 112 (which fix the above structural members to the reverse surface of the strip-shaped sheet 102) are shown such that their positional relationships can be understood. In actuality, as these structural members are fixed to the reverse of the strip-shaped sheet 102, they cannot be seen from the front surface.

FIG. 9 and FIG. 10 also show the surface fasteners 112 which fix the second coupling portions 108 and the connecting cables 120 to the front surface of the main sheet 101. As shown in FIG. 9 and FIG. 10, by fixing the second coupling portions 108 and the connecting cables 120 to the front surface of the main sheet 101 using the surface fasteners 112, when the solar cell sheet 100 is installed outdoors, it is possible to prevent the second coupling portions 108 and the connecting cables 120 from being removed from the main sheet 101 or from being blown away by exposure to the wind.

Various devices can be used as an attaching device to attach the main sheet 101 and the strip-shaped sheet 102 to each other, but as the strip-shaped sheet 102 is frequently removed from and attached to the main sheet 101, it is preferable to use, as the attaching device, a device that allows the strip-shaped sheet 102 to be easily attached to and removed from the main sheet 101.

FIG. 10 shows the surface fasteners 112 as the attaching device. By providing the surface fasteners 112 on both the main sheet 101 and the strip-shaped sheet 102, the strip-shaped sheet 102 can be easily removed from and attached to the main sheet 101.

The main sheet 101 is installed such that it is supported by the support 110 as shown in FIG. 1, but it may be installed directly on the ground. Thus, the main sheet 101 may be provided with through-holes 113, as shown in FIG. 9, to enable the main sheet 101 to be installed on the ground. The through-holes 113 may each be provided with grommets. By providing the main sheet 101 with the through-holes 113, pegs or similar fixing members can be knocked into the through-holes 113 and the main sheet 101 can thus be fixed to the ground.

Note that, in FIG. 9, the through-holes 113 are provided in the main sheet 101 in order to fix the main sheet 101 to the ground, but the present invention is not limited to this example. For example, loops of cord (peg loops) may be provided on each edge of the main sheet 101, into which the above-described fixing members can be knocked in order to fix the main sheet 101 to the ground.

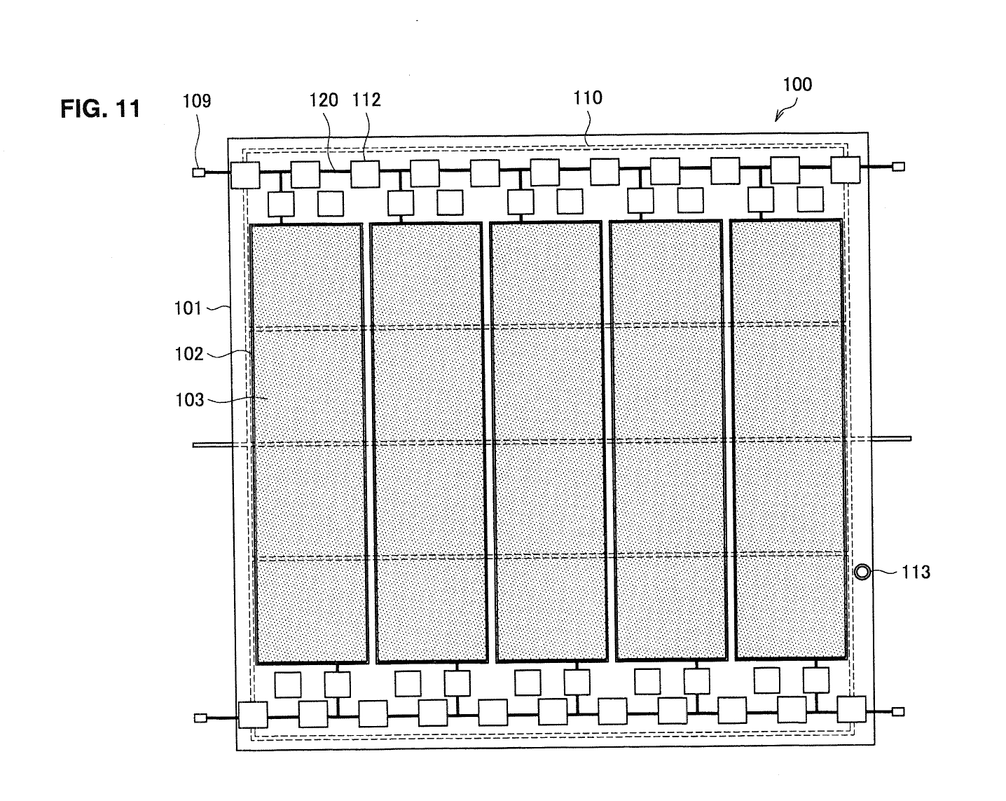

FIG. 11 is an explanatory diagram showing the solar cell sheet 100 in a state in which five of the strip-shaped sheets 102 are attached to the main sheet 101. FIG. 11 shows the support 110 that supports the main sheet 101 and also shows a plurality of the surface fasteners 112 that are used to fix the second coupling portions 108 and the connecting cables 120 shown in FIG. 2 etc. to the main sheet 101. Note that, for ease of explanation, FIG. 11 shows a state in which the solar cell panels 103 are not attached to the strip-shaped sheets 102.

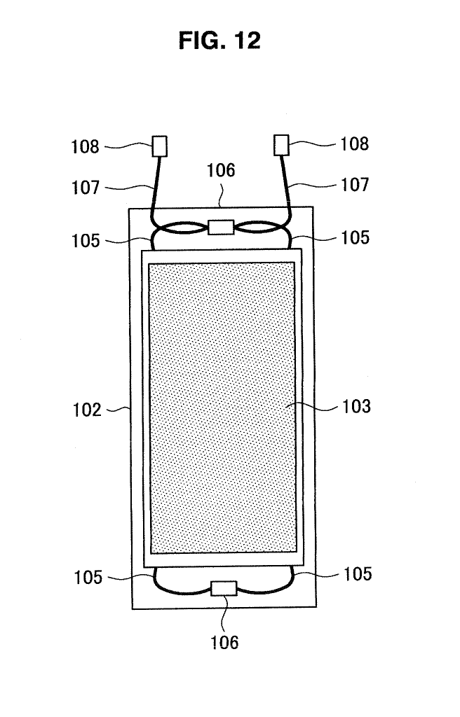

FIG. 12 is an explanatory diagram showing a state in which the strip-shaped sheet 102 to which the solar cell panels 103 are attached is folded over in a center section along the long edges (in the lengthwise direction). In the present embodiment, a case is described in which the two solar cell panels 103 are attached to the strip-shaped sheet 102, and that example of attachment is as shown, for example, in FIG. 9 and FIG. 10.

Here, each of the solar cell panels 103 is attached to the strip-shaped sheet 102 such that the solar cell panel 103 is substantially symmetrical with respect to the fold of the folded over section. Although the present embodiment shows an example in which two of the solar cell panels 103 are used, an even number of the solar cell panels 103 may be attached to each of the strip-shaped sheets 102. When an even number of the solar cell panels 103 are attached to the strip-shaped sheet 102, the strip-shaped sheet 102 can be folded to roughly the size of the solar cell panel 103 by folding over the strip-shaped sheet 102 at gaps between the adjacent solar cell panels 103.

It should also be noted that, if the connectors 104 are thicker than the solar cell panels 103, when the strip-shaped sheet 102 to which two of the solar cell panels 103 are attached is folded over, it is preferable to fold the strip-shaped sheet 102 at the gaps between the solar cell panels 103 such that the connectors 104 do not overlap.

In this way, the strip-shaped sheet 102 to which the solar cell panels 103 are attached can be efficiently stored in a limited space by folding over the strip-shaped sheet 102, to which the solar cell panels 103 are attached, at the center section in the lengthwise direction, or by folding the strip-shaped sheet 102 at the gaps between the solar cell panels 103.

As described above, the solar cell panels 103 are formed to be flexible, and so, from the point of view of storage space, the strip-shaped sheet 102 can be efficiently stored in a limited space by rolling up the strip-shaped sheet 102, to which the solar cell panels 103 are attached, in the lengthwise direction. However, if the strip-shaped sheet 102 is stored in a rolled up state for a long period of time, the shape of the strip-shaped sheet 102 and the solar cell panels 103 is affected by being rolled up. Therefore, when the strip-shaped sheet 102 that has been stored in a rolled up state is opened out, the solar cell panels 103 attached to the strip-shaped sheet 102 are also rounded over. Thus, until the solar cell panels 103 return to a flat surface shape, irradiated sunlight is not efficiently received by the whole light receiving surface, and solar power generation by the solar cell panels 103 cannot be performed efficiently.

In contrast, if the strip-shaped sheet 102 to which the solar cell panels 103 are attached is stored by folding in the center section in the lengthwise direction, the above-described type of problem does not arise. In particular, even when the strip-shaped sheet 102 that has been stored is opened out, the solar cell panels 103 have been kept in a flat state, and irradiation of sunlight is therefore efficiently received by the whole light receiving surface immediately after the strip-shaped sheet 102 is attached to the main sheet 101. Thus, solar power generation by the solar cell panels 103 can be performed efficiently.

By forming the solar cell sheet 100 in this way, the solar cell sheet 100 according to the first embodiment of the present invention allows power generation by the irradiation of sunlight onto the solar cell panels 103, and at the same time, the strip-shaped sheet 102 to which the solar cell panels 103 are attached can easily be attached to and removed from the main sheet 101, and thus portability can be improved.

As described above, according to the first embodiment of the present invention, the solar cell sheet 100 can be structured to make power generation possible by irradiation of sunlight in a location at which outdoors power generation is necessary, by attaching to the main sheet 101 the strip-shaped sheet 102 to which the two solar cell panels 103 are attached.

The solar cell sheet 100 according to the first embodiment of the present invention mainly includes the strip-shaped sheet 102 to which the solar cell panels 103 are attached and the main sheet 101 to which the strip-shaped sheets 102 are attached. With this structure, convenience is improved when the solar cell sheet 100 is installed outdoors. In the first embodiment of the present invention, the rectangular solar cell panels 103 are attached to the rectangular strip-shaped sheet 102 such that the lengthwise direction of the strip-shaped sheet 102 is aligned with the lengthwise direction of the solar cell panels 103. In addition, the solar cell panels 103 are attached to the strip-shaped sheet 102 such that the strip-shaped sheet 102 can be folded over in the center section in the lengthwise direction. With this structure, portability of the strip-shaped sheet 102 to which the solar cell panels 103 are attached can be improved.

When the solar cell panels 103 are attached to the strip-shaped sheet 102, the connectors 104 and the lead wires 105 are passed through the connector holes 111 provided in the strip-shaped sheet 102 and the connectors 104 and the lead wires 105 are positioned on the reverse surface of the strip-shaped sheet 102, such that the connectors 104 and the lead wires 105 are not exposed on the front surface of the strip-shaped sheet 102. By positioning the connectors 104 and the lead wires 105 on the reverse surface of the strip-shaped sheet 102 in this way, the connectors 104 and the lead wires 105 are not exposed on the front surface of the strip-shaped sheet 102, and the solar cell panels 103 can be attached to the strip-shaped sheet 102 without the connectors 104 and the lead wires 105 causing any obstruction to the irradiation of sunlight onto the solar cell panels 103.

It is preferable to fix the connectors 104, the lead wires 105, the first coupling portions 106 and the extension cables 107 to the reverse surface of the strip-shaped sheet 102 using a device that allows these structural members to be easily attached and removed, in order to improve maintainability. For example, it is preferable for these structural members to be attached using the type of surface fastener 112 described above. In addition, it is also preferable for the attachment between the main sheet 101 and the strip-shaped sheet 102 to use an attaching device that allows easy attachment and removal, such as using the type of surface fastener 112 described above.

### 2. SECOND EMBODIMENT

In the above-described first embodiment of the present invention, the solar cell sheet 100 is described in which the rectangular solar cell panels 103 are attached to the rectangular strip-shaped sheet 102 such that the lengthwise direction of the strip-shaped sheet 102 is aligned with the lengthwise direction of the solar cell panels 103.

The present invention is not limited to an example relating to attaching solar cell panels to a strip-shaped sheet. In a second embodiment of the present invention, a solar cell sheet will be described in which a rectangular strip-shaped sheet and similarly rectangular solar cell panels are attached such that the lengthwise direction of the strip-shaped sheet and the lengthwise direction of the solar cell panels are respectively perpendicular to each other.

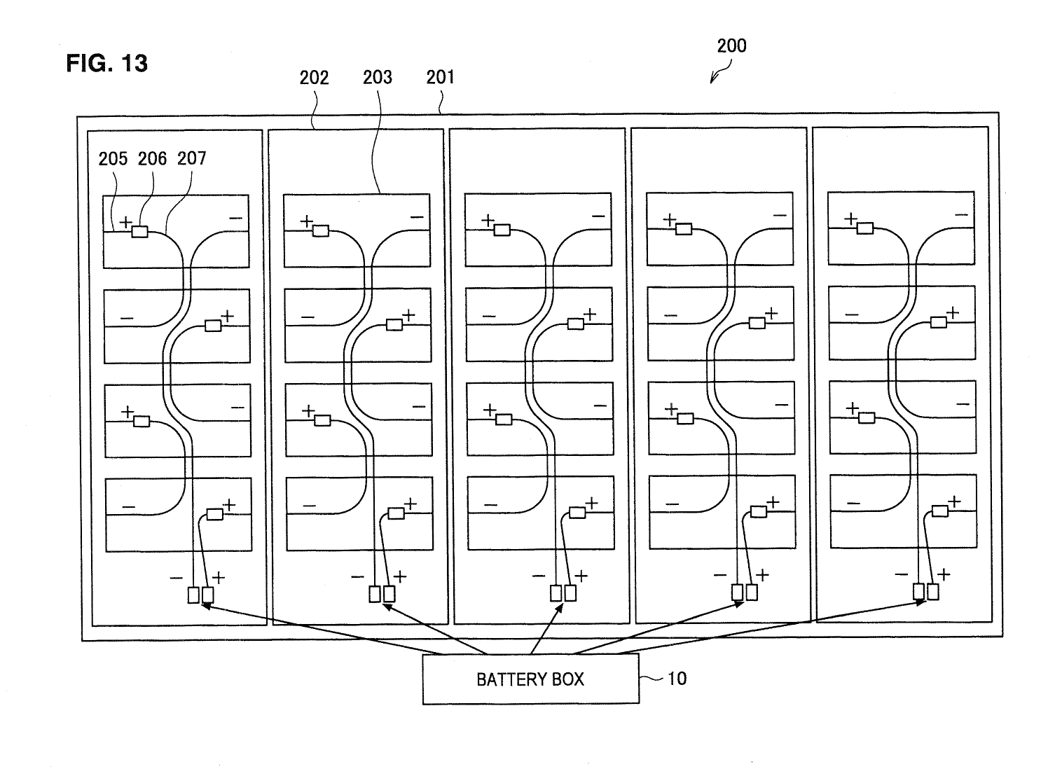

FIG. 13 is an explanatory diagram showing a structure of a solar cell sheet 200 according to the second embodiment of the present invention. Hereinafter, the structure of the solar cell sheet 200 according to the second embodiment of the present invention will be explained with reference to FIG. 13.

As shown in FIG. 13, the solar cell sheet 200 according to the second embodiment of the present invention includes a main sheet 201, strip-shaped sheets 202 and solar cell panels 203.

Similarly to the main sheet 101 of the solar cell sheet 100 according to the first embodiment of the present invention, the main sheet 201 is a sheet material onto which are mounted the strip-shaped sheets 202 to which the solar cell panels 203 are attached. Similarly to the strip-shaped sheet 102 of the solar cell sheet 100 according to the first embodiment of the present invention, the strip-shaped sheet 202 is a sheet material to which the solar cell panels 203 are attached. The strip-shaped sheet 202 is formed to be long and narrow, and is smaller than the main sheet 201, as shown in FIG. 13.

Similarly to the solar cell panel 103 of the solar cell sheet 100 according to the first embodiment of the present invention, the solar cell panel 203 is a panel on which is laid a solar cell, and the solar cell generates electric power by receiving irradiation of sunlight. In the present embodiment, four of the solar cell panels 203 are arranged in series and attached to a single one of the strip-shaped sheets 202. Further, as shown in FIG. 13, in the second embodiment of the present invention, the rectangular solar cell panels 203 are attached to the rectangular strip-shaped sheet 202 such that the lengthwise direction of the strip-shaped sheet 202 and the lengthwise direction of the solar cell panels 203 intersect orthogonally with each other.

Five of the strip-shaped sheets 202 are attached to the main sheet 201 of the solar cell sheet 200 according to the second embodiment of the present invention shown in FIG. 13, but it goes without saying that, in the present invention, the number of strip-shaped sheets attached to the main sheet is not limited to this example.

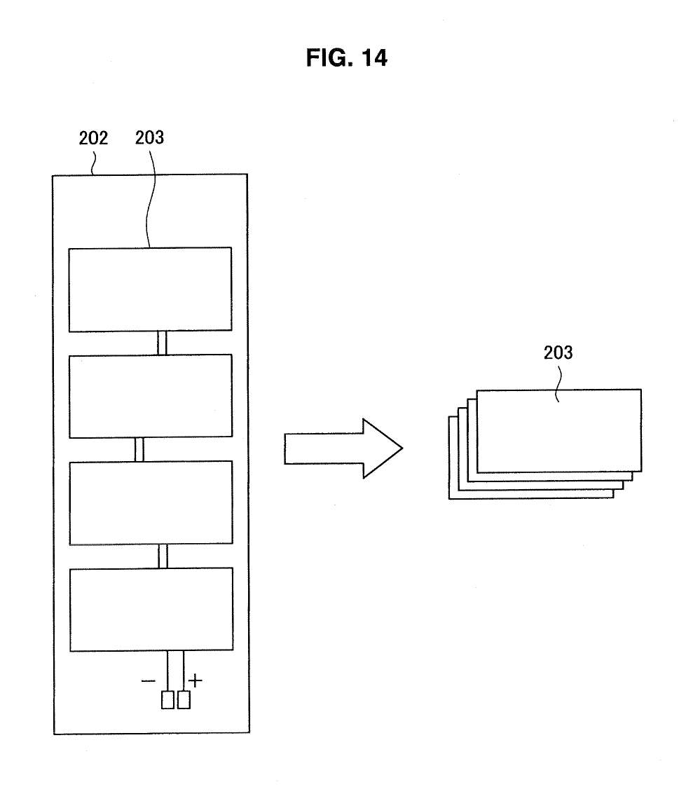

Next, a storage example of the strip-shaped sheet 202 according to the second embodiment of the present invention will be explained. FIG. 14 is an explanatory diagram showing the storage example of the strip-shaped sheet 202 according to the second embodiment of the present invention.

As described above, four of the solar cell panels 203 are attached to the single strip-shaped sheet 202. The four solar cell panels 203 are attached to the strip-shaped sheet 202 in positions such that they overlap with each other when the strip-shaped sheet 202 is twice folded over in the lengthwise direction. As a result, when folding up and storing the strip-shaped sheet 202, the four solar cell panels 203 are folded over each other in one place, as shown on the right side in FIG. 14.

The storability and portability of the strip-shaped sheet 202 to which the solar cell panels 203 are attached can be improved by attaching the solar cell panels 203 to the strip-shaped sheet 202 in this manner.

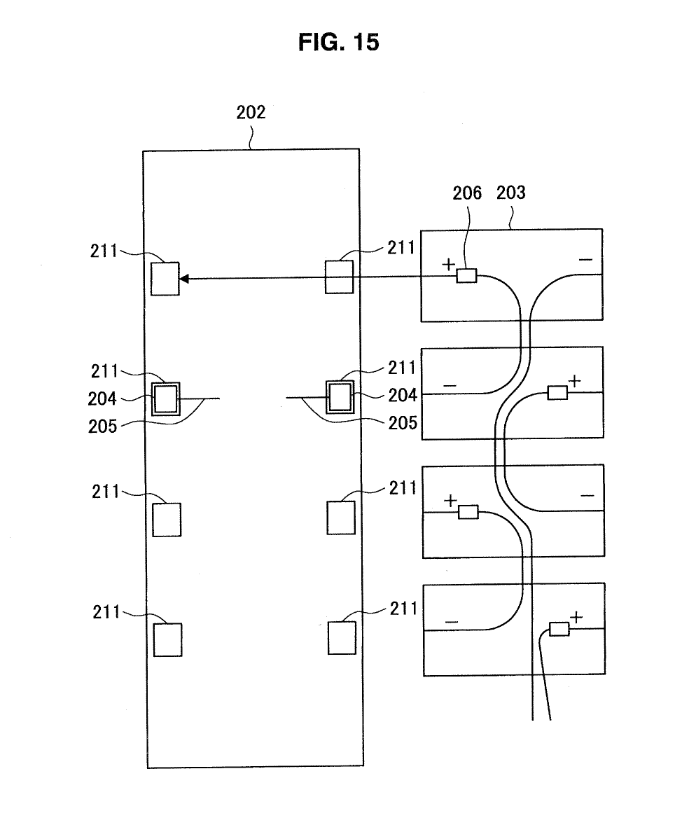

Next, connections between the solar cell panels 203 and connectors 204 according to the second embodiment of the present invention will be explained. FIG. 15 is an explanatory diagram showing connections between the solar cell panels 203 and the connectors 204 according to the second embodiment of the present invention. Note that the connectors 204 are used to connect the solar cell panels 203 to the lead wires 205 in order to supply the electric power generated by the solar cell panels 203 to the battery box 10.

As shown in FIG. 15, eight connector holes 211 are provided in the strip-shaped sheet 202. The connector holes 211 are provided in the strip-shaped sheet 202 in order to pass the lead wires 205 through to the reverse surface of the strip-shaped sheet 202, and a size of the connector holes 211 accords with a shape of the connectors 204.

By providing the connector holes 211 in the strip-shaped sheet 202 in this way, the connectors 204 and the lead wires 205 can be fixed to the reverse surface of the strip-shaped sheet 202.

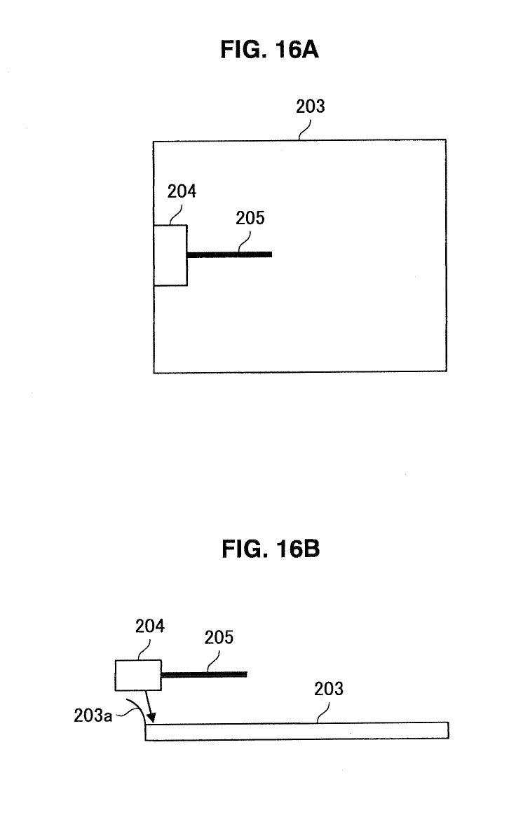

Next, a structure of a connection between the solar cell panel 203 and the connector 204 will be explained. FIG. 16A and FIG. 16B are explanatory diagrams each showing a structure of the connection between the solar cell panel 203 and the connector 204.

As shown in FIG. 16A and FIG. 16B, in the present embodiment, the connector 204 is attached to a center portion of an edge of the solar cell panel 203. When attaching the solar cell panel 203 and the connector 204, the connector 204 is attached to the solar cell panel 203 such that a wire 203a that extends from the edge of the solar cell panel 203 is connected with the lead wire 205 inside the connector 204. The wire 203a and the lead wire 205 may be connected to each other by soldering.

Note that the connector 204 and the lead wire 205 may be fixed to the strip-shaped sheet 202 using a surface fastener, similarly to the above-described first embodiment of the present invention.

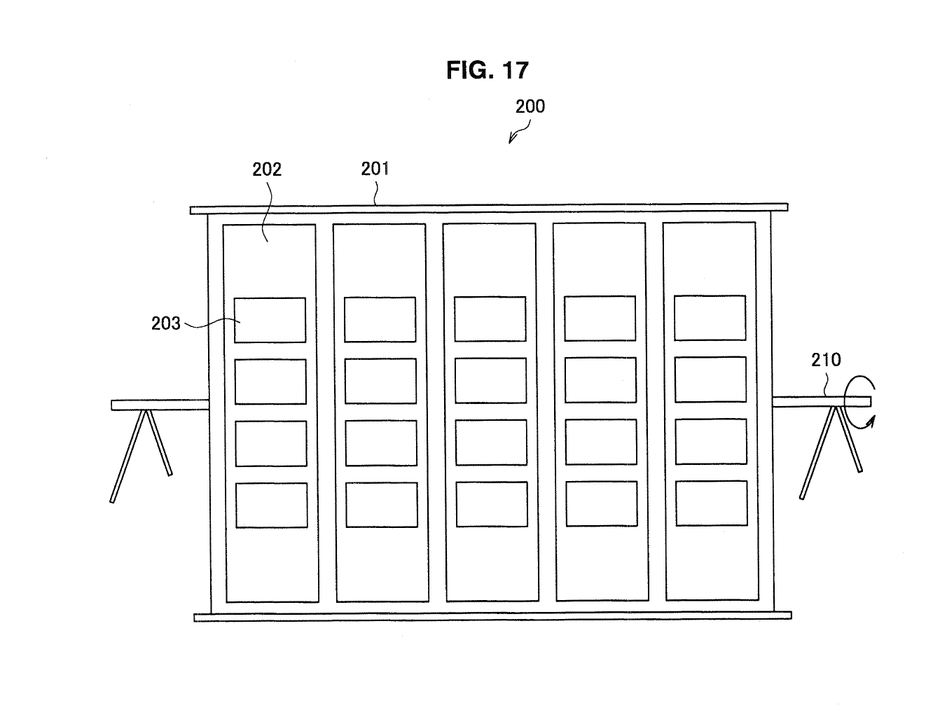

Next, an installation example of the solar cell sheet 200 according to the second embodiment of the present invention will be explained. FIG. 17 is an explanatory diagram showing an installation example of the solar cell sheet 200 according to the second embodiment of the present invention.

The solar cell sheet 200 according to the second embodiment of the present invention is installed, for example, by fixing the solar cell sheet 200 to a support 210. The solar cell sheet 200 that is fixed to the support 210 shown in FIG. 17 can be rotated, centering around an axis of the support 210. In this way, an orientation of the solar cell sheet 200 can be changed in accordance with movement of the sun, and the solar cell sheet 200 can be efficiently irradiated by sunlight.

Of course, as explained above in the first embodiment of the present invention, on the solar cell sheet 200 according to the second embodiment of the present invention, the main sheet 201 may be provided with through-holes. The solar cell sheet 200 can be fixed to the ground by providing the main sheet 201 with the through-holes and knocking fixing members, such as pegs or the like, through the through-holes.

According to the above-described second embodiment of the present invention, the solar cell sheet 200 can be obtained by attaching the rectangular solar cell panels 203 to the rectangular strip-shaped sheet 202 such that the long edges of the strip-shaped sheet 202 and the long edges of the solar cell panels 203 are respectively perpendicular to each other.

In the present embodiment, four of the solar cell panels 203 are attached to the single strip-shaped sheet 202. As shown on the left side in FIG. 14, the four solar cell panels 203 are attached to the strip-shaped sheet 202 in positions such that they overlap with each other when the strip-shaped sheet 202 is twice folded over in the lengthwise direction. As a result, when storing the strip-shaped sheet 202, the four solar cell panels 203 are folded over each other in one place, as shown on the right side in FIG. 14. The storability and portability of the strip-shaped sheet 202 to which the solar cell panels 203 are attached can be improved by attaching the solar cell panels 203 to the strip-shaped sheet 202 in this manner.

### 3. THIRD EMBODIMENT

In the above-described first embodiment of the present invention, in the explanation of the solar cell sheet 100, the solar cell panels 103 are attached to the strip-shaped sheet 102 such that the lengthwise direction of the strip-shaped sheet 102 is aligned with the lengthwise direction of the solar cell panels 103. Further, in the above-described second embodiment of the present invention, in the explanation of the solar cell sheet 200, the solar cell panels 203 are attached to the strip-shaped sheet 202 such that the lengthwise direction of the strip-shaped sheet 202 and the lengthwise direction of the solar cell panels 203 are respectively perpendicular to each other.

However, the attachment of the solar cell panels to the strip-shaped sheet is not limited to the above-described examples. For example, by attaching the solar cell panels to the strip-shaped sheets such that when attaching to the main sheet, the solar cell panels form a mesh which has a predetermined angle with respect to each edge of the main sheet, an effect is obtained that deformation of the main sheet to which the solar cell panels are attached does not easily occur.

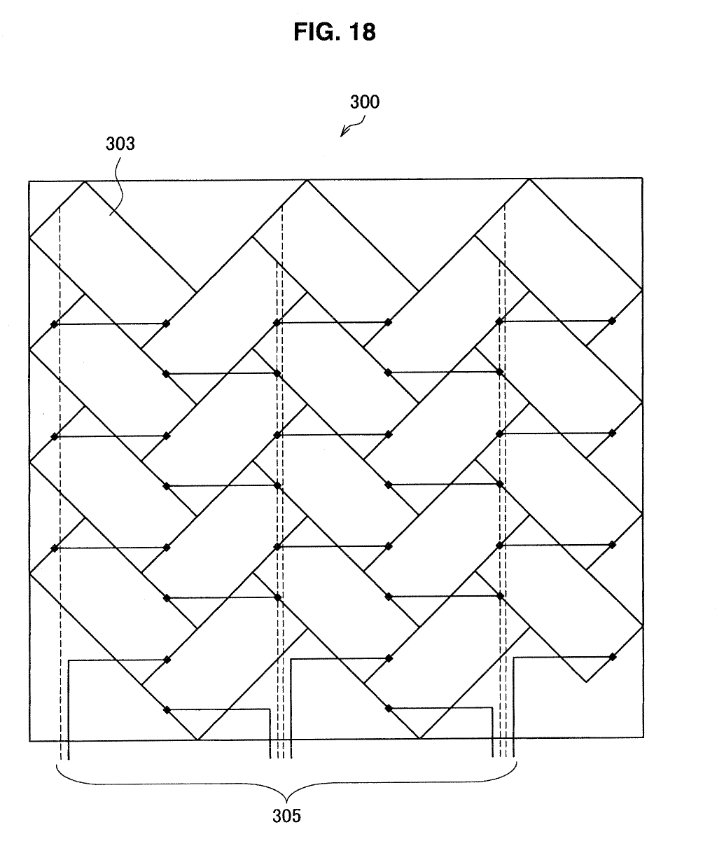

FIG. 18 is an explanatory diagram showing a structure of a solar cell sheet 300 according to a third embodiment of the present invention. Hereinafter, the structure of the solar cell sheet 300 according to the third embodiment of the present invention will be explained with reference to FIG. 18.

The solar cell sheet 300 shown in FIG. 18 includes a main sheet 301 on which solar cell panels 303 are arranged in a mesh layout. By arranging the solar cell panels 303 on the main sheet 301 in this way, when the solar cell sheet 300 is installed on a support or the like, an effect is obtained that deformation of the main sheet 301 does not easily occur.

It should be noted that, although not shown in FIG. 18, similarly to each of the above-described embodiments, the solar cell panels 303 are attached to strip-shaped sheets. A mode of attachment of the solar cell panels 303 to the strip-shaped sheets will be explained later.

FIG. 18 shows lead wires 305, which supply electric power generated by the solar cell panels 303 to a battery box. Note that, in FIG. 18, for ease of explanation, the lead wires 305 connected between the solar cell panels 303 are indicated by solid lines. However, similarly to each of the above-described embodiments, it is preferable for the lead wires 305 to be fixed to the reverse side of the strip-shaped sheet such that they do not obstruct irradiation of sunlight onto the solar cell panels 303.

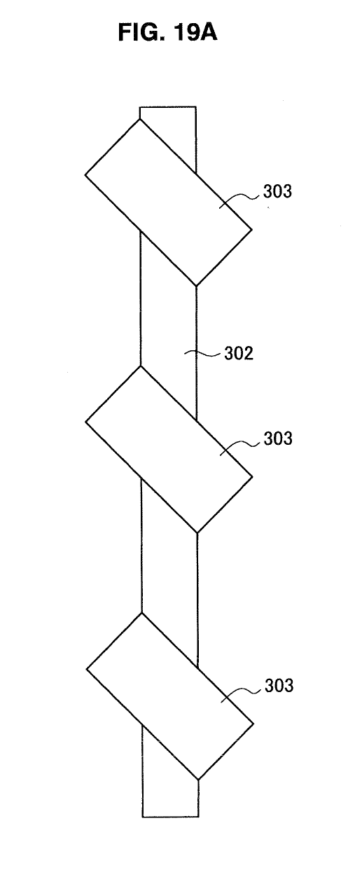

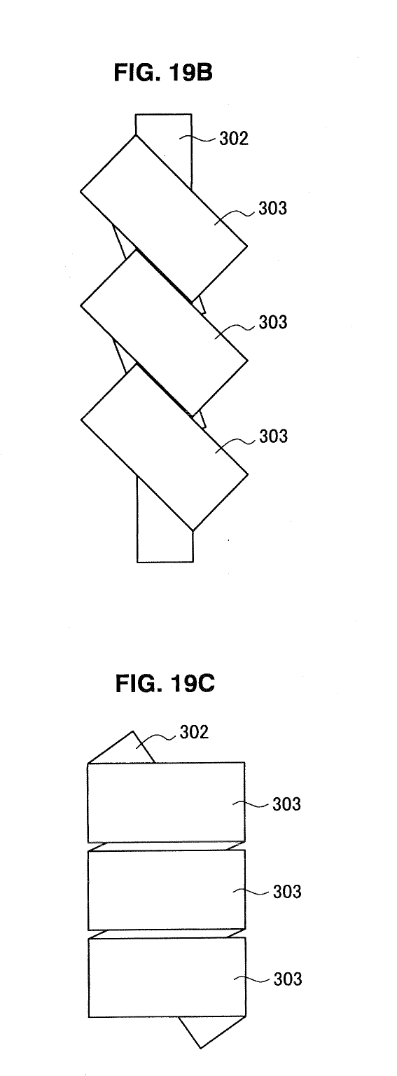

FIG. 19A, FIG. 19B and FIG. 19C are explanatory diagrams each showing a mode of attachment of the solar cell panels 303 onto a strip-shaped sheet 302, on the solar cell sheet 300 according to the third embodiment of the present invention.

As shown in FIG. 19A, on the solar cell sheet 300 according to the third embodiment of the present invention, in order to arrange the solar cell panels 303 on the main sheet 301 in a mesh layout, the solar cell panels 303 are attached to the strip-shaped sheet 302 at a predetermined angle. When the solar cell panels 303 are attached to the strip-shaped sheet 302, it is preferable for a predetermined interval to be maintained between the solar cell panels 303, as shown in FIG. 19A, taking into account attachment of the solar cell panels 303 on the main sheet 301 and storage of the solar cell panels 303.

By attaching the solar cell panels 303 to the strip-shaped sheet 302 while maintaining the predetermined interval, as shown in FIG. 19A, when the solar cell panels 303 are mounted on the main sheet 301, the strip-shaped sheets 302 can be arranged such that the solar cell panels 303 form a mesh, as shown in FIG. 19B. Further, by attaching the solar cell panels 303 to the strip-shaped sheet 302 while maintaining the predetermined interval, when the solar cell panels 303 are stored, the strip-shaped sheet 302 can be folded over such that an orientation of the solar cell panels 303 is aligned, as shown in FIG. 19C. Then, similarly to the method explained with reference to FIG. 14, the strip-shaped sheet 302 to which the solar cell panels 303 are attached can be folded up small.

As a result, by attaching the solar cell panels 303 to the strip-shaped sheet 302 as shown in FIG. 19A, when the solar cell sheet 300 is installed on the support or the like, the solar cell panels 303 can be arranged on the main sheet 301 as shown in FIG. 18, such that deformation of the main sheet 301 does not easily occur. At the same time, at the time of storage, the orientation of the solar cell panels 303 can be aligned as shown in FIG. 19C, and thus storability and portability can be improved.

### 4. CONCLUSION

According to each of the embodiments of the present invention described above, by attaching a strip-shaped sheet, to which a plurality of solar cell panels are attached, to a main sheet, a solar cell sheet can be formed that is capable of generating electric power by irradiation of sunlight in a location in which electric power is required outdoors. The solar cell sheet according to each of the embodiments of the present invention mainly includes the strip-shaped sheets to which the solar cell panels are attached, and a main sheet to which the strip-shaped sheets are attached. With the above-described structure, convenience is improved when the solar cell sheet is installed in an outdoors location.

When the solar cell panels are attached to the strip-shaped sheet, connectors and lead wires that supply the electric power generated by the solar cell panels to a battery box are not exposed to the front surface of the strip-shaped sheet. For this, connector holes corresponding generally to a size of the connectors are provided, for example, in the strip-shaped sheet and the connectors and lead wires can be fixed to the reverse surface of the strip-shaped sheet. The lead wires can be fixed to the strip-shaped sheet in this way such that they do not obstruct irradiation of sunlight onto the solar cell panels, and thus it is possible not to cause deterioration in the power generation efficiency of the solar cell panels.

Then, when the strip-shaped sheet to which the solar cell panels are attached is stored or put away, the strip-shaped sheet is folded over such that the solar cell panels overlap with each other. In this way, the strip-shaped sheet to which the solar cell panels are attached can be stored efficiently in a limited space. Also, at the time of use, by opening out the folded over strip-shaped sheet, the strip-shaped sheet can be in a state in which it can immediately be used.

It should be understood by those skilled in the art that various modifications, combinations, sub-combinations and alterations may occur depending on design requirements and other factors insofar as they are within the scope of the appended claims or the equivalents thereof.

For example, in each of the above-described embodiments, the solar cell panels 103, 203 and 303 are all described as having a rectangular shape, but the present invention is not limited to this example. The shape of the solar cell panels may be a square, for example, and the square-shaped solar cell panels may be attached to the above-described strip-shaped sheets 102, 202 and 302.

Further, for example, in each of the above-described embodiments, a method is adopted in which the strip-shaped sheets are attached to the main sheet, but the present invention is not limited to this example. For example, a method may be adopted in which peg loops or through-holes are provided in the strip-shaped sheets, and the strip-shaped sheets may be fixed directly to the ground surface.

The present application contains subject matter related to that disclosed in Japanese Priority Patent Application JP 2010-62592 filed in the Japan Patent Office on Mar. 18, 2010, the entire content of which is hereby incorporated by reference.

What is claimed is:

1. A solar cell sheet comprising:
a solar cell panel that generates electric power by receiving irradiation of sunlight;
a first sheet to which a number of the solar cell panels are attached such that a reverse surface of a light receiving surface of each of the solar cell panels is attached to the first sheet with a predetermined interval between each of the solar cell panels, the number of the solar cell panels being sufficient to obtain desired electric power; and
a second sheet to which is removably attached to the at least one first sheet to which the solar cell panels are attached, the at least one first sheet being removably attached to the second sheet on a reverse surface to a surface on which the solar cell panels are attached.

2. The solar cell sheet according to claim 1,
wherein the solar cell panels are attached to the first sheet with a same orientation.

3. The solar cell sheet according to claim 1,
wherein the first sheet includes connector holes through which are passed lead wires, which supply electric power generated by the solar cell panels, and connectors, which connect each of the solar cell panels and the lead wires, the lead wires and the connectors being passed through to the reverse surface to the surface on which the solar cell panels are attached.

4. The solar cell sheet according to claim 3,
wherein the lead wires are fixed to the reverse surface of the first sheet using surface fasteners.

5. The solar cell sheet according to claim 1,
wherein a shape of the solar cell panel is a rectangle, and the solar cell panel is attached such that a lengthwise orientation of the solar cell panel is aligned with a lengthwise orientation of the first sheet.

6. The solar cell sheet according to claim 5,
wherein two of the solar cell panels are attached to each one of the first sheets, the solar cell panels being attached with a gap between the solar cell panels such that, when the first sheet is folded over at a gap section between the solar cell panels, the solar cell panels oppose each other and the lead wires which supply the electric power generated by the solar cell panels and the connectors that connect the lead wires to the solar cell panels do not overlap with each other.

7. The solar cell sheet according to claim 1,
wherein a shape of the solar cell panel is a rectangle and the solar cell panel is attached such that a lengthwise orientation of the solar cell panel orthogonally intersects with a lengthwise orientation of the first sheet.

8. The solar cell sheet according to claim 7,
wherein an even number of the solar cell panels are attached to each one of the first sheets, the solar cell panels being attached such that, when the first sheet is folded in the lengthwise direction such that folded over lengths are equal to the even number, a position of the solar cell panels matches.

9. The solar cell sheet according to claim 1,
wherein the solar cell panels are attached such that the solar cell panels are at a predetermined angle to a long side of the first sheet.

10. The solar cell sheet according to claim 1,
wherein the solar cell panels are arranged as a mesh when the solar cell panels are attached to the second sheet.

11. The solar cell sheet according to claim 1,
wherein a shape of the solar cell panel is a square.

12. The solar cell sheet according to claim 1,
wherein the first sheet and the second sheet are sheets that have flame resistant properties.

13. A solar cell sheet comprising:
a solar cell panel that generates electric power by receiving irradiation of sunlight; and
a sheet to which a number of the solar cell panels are attached such that a reverse surface of a light receiving surface of each of the solar cell panels is attached to the sheet with a predetermined interval between each of the solar cell panels, the number of the solar cell panels being sufficient to obtain desired electric power.
